(19) United States
(12) Patent Application Publication
(10) Pub. No.: US 2013/0134845 A1
(43) Pub. Date: May 30, 2013

(54) MOUNTING APPARATUS FOR DATA STORAGE DEVICE

(71) Applicants: HAN-YU LI, Tu-Cheng (TW); HAI-FENG WU, Shenzhen City (CN); GUANG-DONG HE, Shenzhen City (CN)

(72) Inventors: HAN-YU LI, Tu-Cheng (TW); HAI-FENG WU, Shenzhen City (CN); GUANG-DONG HE, Shenzhen City (CN)

(21) Appl. No.: 13/656,789

(22) Filed: Oct. 22, 2012

(30) Foreign Application Priority Data
Nov. 28, 2011 (CN) 201110384381.4

(51) Int. Cl. H05K 7/14; H05K 5/02

(52) U.S. Cl. 312/223.2

(57) ABSTRACT

A mounting apparatus includes a bracket, a cage, and a hand. The bracket includes two sidewalls and two positioning posts extending from the two sidewalls. Each sidewall defines a first cutout. The cage secures a data storage device and defines two sliding slots and a positioning hole. The handle includes a positioning portion and two mounting portions. Each positioning post is received in each sliding slot. The handle is slidable relative to the cage between a locked position and an unlocked position. When the handle is in the locked position, the positioning portion is engaged in the positioning hole, and each mounting portion is engaged in the first cutout. When the handle is in the unlocked position, the positioning portion is disengaged from the positioning hole, the mounting portion is disengaged from the first cutout, and the two positioning post are movable in the two sliding slots.

### BACKGROUND

1. Technical Field

The present disclosure relates to mounting apparatuses, and particularly to a mounting apparatus for data storage devices.

2. Description of Related Art

Data storage devices are used for storing data in electronic devices, such as computers or servers. Each data storage device is generally mounted in a bracket, and then the bracket is mounted in a computer enclosure by screws, which requires a screw driver to secure the screws to the bracket. Disassembly or reassembly of the data storage devices can be tedious and inconvenient. Therefore, there is room for improvement in the art.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the embodiments. Moreover, in the drawings, like reference numerals designate corresponding parts throughout the several views.

FIG. 1 is an exploded, isometric view of one embodiment of a mounting apparatus for a data storage device.

FIG. 2 is an assembled, isometric view of the mounting apparatus of FIG. 1, and a handle is in a locked position.

FIG. 3 is similar to FIG. 2, but the handle is in an unlocked position.

FIG. 4 is an assembled, isometric view of the mounting apparatus of FIG. 1 and the data storage device.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean “at least one.”

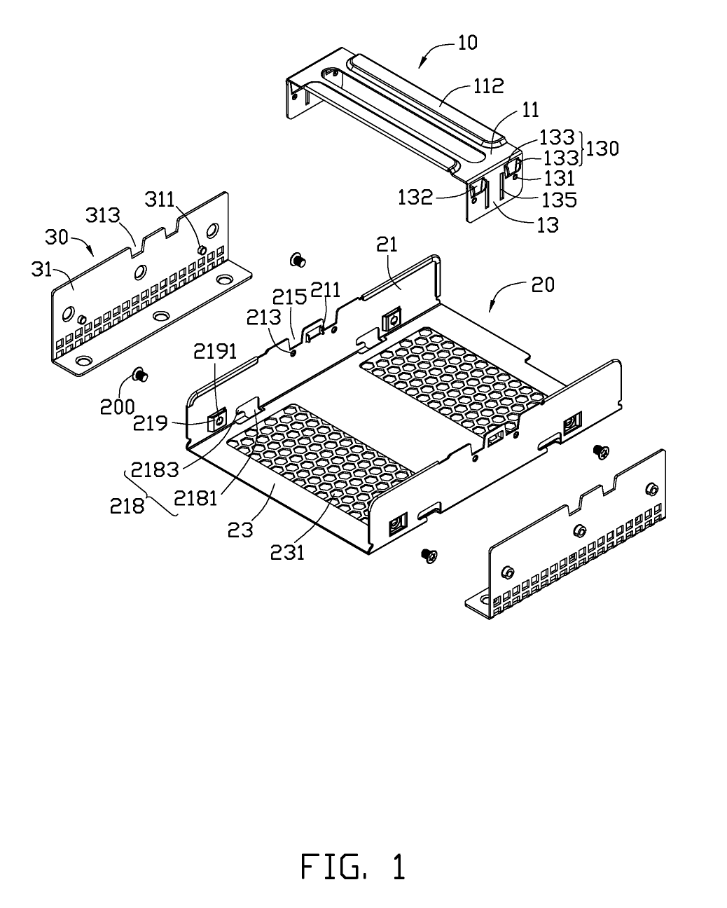

Referring to FIG. 1, a mounting apparatus in accordance with an embodiment is shown. The mounting apparatus comprises a cage 20, a handle 10, and two brackets 30.

The cage 20 comprises two side plates 21 and a bottom plate 23. The bottom plate 23 is perpendicularly connected between the two side plates 21. The two side plates 21 respectively form two limiting pieces 211 extending towards each other. In one embodiment, the two limiting pieces 211 are substantially perpendicular to the two side plates 21. Each of the side plates 21 defines two second cutouts 215, two sliding slots 218, and two positioning holes 213. Each of the second cutouts 215 is defined in a top edge of each of the two side plates 21. Each of the sliding slots 218 is defined in a bottom edge of each of the two side plates 21. The two limiting pieces 211 are located between the two second cutouts 215. In one embodiment, each of the positioning holes 213 is located below each of the two second cutouts 215, and each of the second cutouts 215 is trapezoidal. Each of the sliding slots 218 comprises a guiding portion 2181 and a sliding portion 2183 communicating with the guiding portion 2181. An extending direction of the guiding portion 2181 is substantially perpendicular to an extending direction of the sliding portion 2183. Each of the side plates 21 further comprises two recess portions 219. Each of the recess portions 219 defines a locking hole 2191. The bottom plate 23 defines a plurality of ventilation holes 231.

The handle 10 comprises an operating plate 11 and two mounting plates 13. A protruding portion 112 protrudes from a top surface of the operating plate 11. Two positioning portions 131 and two mounting portions 130 extend from each of the mounting plates 13. Each of the two mounting plates 13 defines two openings 132 and two limiting slots 135. Each of the openings 132 is similar with each of the two second cutouts 215. Each of the mounting portions 130 comprises two mounting pieces 133. The two mounting pieces 133 extend from two side edges of each of the two openings 132. In one embodiment, each of the positioning portions 131 is located below each of the two openings 132, the two limiting slots 135 are located between the two openings 132, and an acute angle is defined between the two mounting pieces 133. Each of the positioning portions 131 can be engaged in each of the two positioning holes 213. Each of the limiting slots 125 can be used for receiving each of the two limiting pieces 211. The two mounting pieces 133 can be engaged in each of the two second cutouts 215. In one embodiment, each of the two positioning portions 131 has an arc-shaped outer surface.

Each of the two brackets 30 comprises a sidewall 31. The sidewall 31 defines two first cutouts 313 corresponding to the two second cutouts 215. Two positioning posts 311 extend inwards from the sidewall 31. In one embodiment, each of the two brackets 30 is “L” shaped. Each of the two brackets 30 can be secured to a chassis (not shown). In another embodiment, the mounting apparatus comprises one of the two brackets 30, which comprises opposite two of the sidewalls 31.

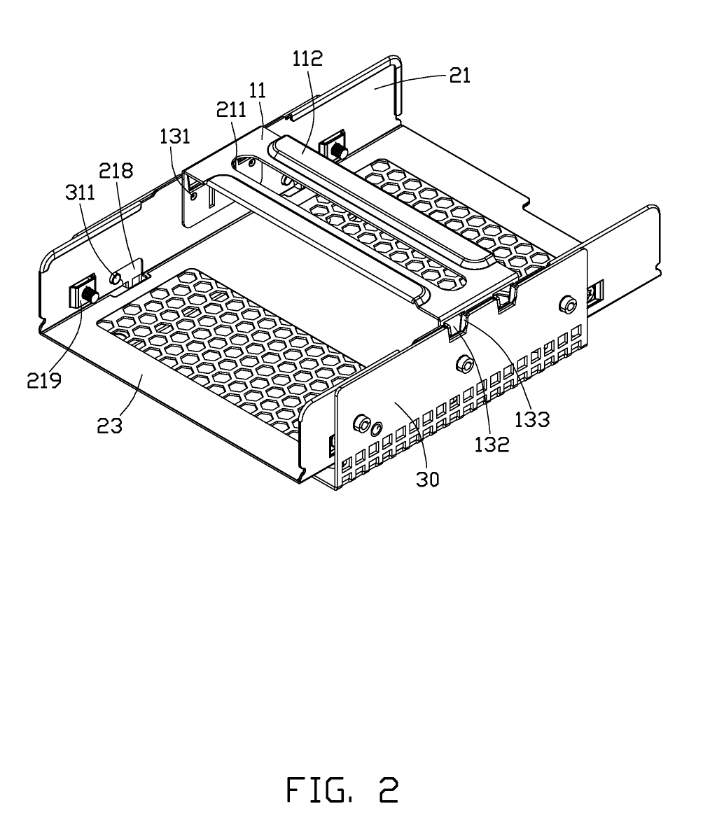

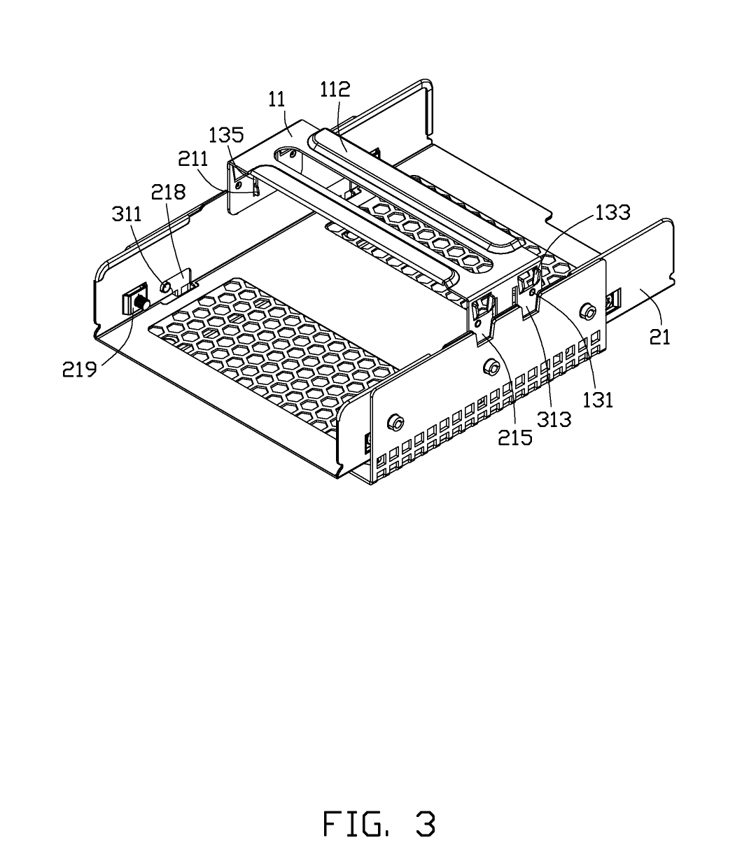

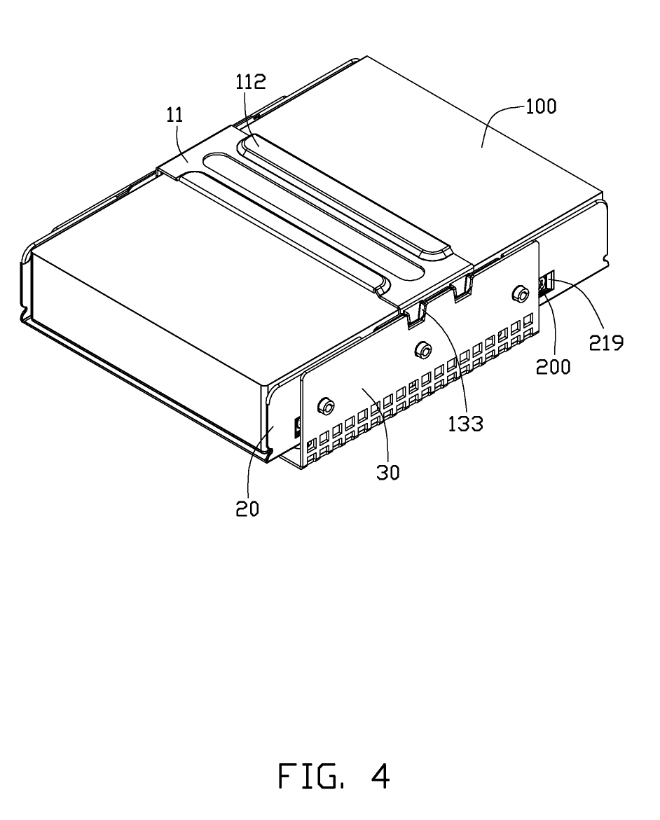

FIGS. 2-4 show that in assembly of the handle 10, the handle 10 is moved to adjacent to the cage 20. The two mounting plates 13 are driven to be elastically deformed towards each other and placed between the two side plates 21, until the two limiting pieces 211 are aligned with the two limiting slots 135. The two mounting plates 13 rebound to receive the two limiting pieces 211 in the two limiting slots 135.

The handle 10 is slidable along the two limiting slots 135 relative to the cage 20 between a locked position and an unlocked position. When the handle 10 is in the locked position, each of the positioning portions 131 is engaged in each of the two positioning holes 213, the two mounting pieces 133 are engaged in each of the two second cutouts 215, and each of the limiting pieces 211 abuts a top edge of each of the two limiting slots 135. When the handle 10 is in the unlocked position, each of the positioning portions 131 is disengaged from each of the positioning holes 213, the two mounting pieces 133 are disengaged from each of the two second cutouts 215, and each of the limiting pieces 211 abuts a bottom edge of each of the limiting slots 135.

The cage 20 is used for securing a data storage device 100. The data storage device 100 is received in the cage 20 and abuts the recess portions 219. A plurality of fasteners 200, such as screws, is engaged with the data storage device 100 through the locking holes 2191, to secure the data storage device 100 to the cage 20.

In assembly of the cage 20, the handle 10 is positioned in the unlocked position. The cage 20 is moved between two of the sidewalls 31, and each of the two positioning posts 311 is aligned with the guiding portion 2181. The cage 20 is moved downwards to slide the positioning post 311 into each of the two sliding slots 218. The cage 20 is moved along a direction substantially parallel to the bottom plate 23 until the positioning post 311 is engaged in an end of the sliding portion 2183. Thus, the cage 20 is prevented from moving along a direction substantially perpendicular to the bottom plate 23. In this position, each of the two first cutouts 313 is aligned with each of the two second cutouts 215. The handle 10 is pressed towards the bottom plate 23, until the handle 10 is placed in the locked position. Each of the two mounting pieces 133 is engaged in each of the two first cutouts 313, to prevent the cage 20 from moving along a direction substantially parallel to the bottom plate 23. The operating plate 11 abuts a top surface of the data storage device 100. A gap (not labeled) is defined between the protruding portion 112 and the top surface of the data storage device 100. The protruding portion 112 is used for absorbing shock from objects, which presses downwards the mounting apparatus.

In disassembly of the cage 20, the handle 10 is moved upwards to the locked position. The cage 20 is movable relative to each of the two brackets 30. The cage 20 is moved to slide the positioning post 311 into the guiding portion 2181 from the sliding portion 2183. Thus, the cage 20 can be removed from each of the two brackets 30.

It is to be understood, however, that even though numerous characteristics and advantages have been set forth in the foregoing description of embodiments, together with details of the structures and functions of the embodiments, the disclosure is illustrative only and changes may be made in detail, especially in the matters of shape, size, and the arrangement of parts within the principles of the disclosure, to the full extent indicated by the broad general meaning of the terms in which the appended claims are expressed.

What is claimed is:

1. A mounting apparatus for a data storage device, the mounting apparatus comprising:
a bracket comprising two sidewalls and two positioning posts; each of the two positioning posts extends from each of the two sidewalls; and each of the two sidewalls defines a first cutout;
a cage configured to secure the data storage device and received between the two sidewalls, and the cage defining two sliding slots and a positioning hole; and
a handle slidably mounted to the cage and comprising a positioning portion and two mounting portions;
wherein each of the two positioning posts is received in each of the two sliding slots; the handle is slidable relative to the cage between a locked position and an unlocked position; when the handle is in the locked position, the positioning portion is engaged in the positioning hole, and each of the two mounting portions is engaged in the first cutout; when the handle is in the unlocked position, the positioning portion is disengaged from the positioning hole, each of the two mounting portions is disengaged from the first cutout, and the two positioning posts are movable in the two sliding slots.

2. The mounting apparatus of claim 1, wherein the cage comprises two side plates located between the two sidewalls; each of the two sliding slots is defined in each of the two side plates; the handle comprises an operating plate and two mounting plates connected to the operating plate; the positioning portion and the two mounting portions extend from one of the two mounting plates; the two mounting plates are located between the two side plates; and the operating plate is substantially perpendicular to the two side plates.

3. The mounting apparatus of claim 2, wherein each of the two mounting plates defines a limiting slot; a limiting piece extends from each of the two side plates; the limiting piece is received in the limiting slot; and the limiting piece is slid in the limiting slot when the handle is slid between the locked position and the unlocked position.

4. The mounting apparatus of claim 3, wherein the limiting piece is substantially perpendicular to the operating plate and the two side plates.

5. The mounting apparatus of claim 3, wherein an extending direction of the limiting slot is substantially perpendicular to the operating plate.

6. The mounting apparatus of claim 2, wherein each of the two sliding slots comprises a guiding portion and a sliding portion substantially perpendicular to the guiding portion; each of the two positioning posts is engaged in the sliding portion through the guiding portion; and an extending direction of the sliding portion is substantially parallel to the operating plate.

7. The mounting apparatus of claim 2, wherein each of the two side plates defines a second cutout; when the handle is in the locked position, each of the two mounting portions is engaged in the second cutout; and when the handle is in the unlocked position, each of the two mounting portions is disengaged from the second cutout.

8. The mounting apparatus of claim 7, wherein each of the two mounting portions comprises two mounting pieces; when the handle is in the locked position, the two mounting pieces abut two side edges of each of the first cutout and the second cutout.

9. The mounting apparatus of claim 8, wherein an acute angle is defined between the two mounting pieces.

10. The mounting apparatus of claim 1, wherein the first cutout is substantially trapezoidal.

11. A mounting apparatus for a data storage device, the mounting apparatus comprising:
a bracket comprising two sidewalls and two positioning posts; each of the two positioning posts extends from each of the two sidewalls; and each of the two sidewalls defines a first cutout;
a cage configured to secure the data storage device and received between the two sidewalls, the cage comprising two opposite side plates, and each of the two side plates defining two sliding slots and a second cutout aligned with the first cutout; and
a handle slidably mounted to the cage and comprising two mounting portions;
wherein each of the two positioning posts is received in each of the two sliding slots; the handle is slidable relative to the cage between a locked position and an unlocked position; when the handle is in the locked position, each of the two mounting portions is engaged in the first cutout and the second cutout, and each of the two mounting portions is elastically deformable to abut edges of the first cutout and edges of the second cutout; and when the handle is in the unlocked position, each of the two mounting portions is disengaged from the first cutout and the second cutout, and the two positioning posts are movable in the two sliding slots.

12. The mounting apparatus of claim 11, wherein each of the two side plates further defines a positioning hole, and the handle further comprise a positioning portion; when the handle is in the locked position, the positioning portion is engaged in the positioning hole; and when the handle is in the unlocked position, the positioning portion is disengaged from the positioning hole.

13. The mounting apparatus of claim 12, wherein the handle comprises an operating plate and two mounting plates connected to the operating plate; the positioning portion and the two mounting portions extend from one of the two mounting plates; the two mounting plates are located between the two side plates; and the operating plate is substantially perpendicular to the two side plates.

14. The mounting apparatus of claim 13, wherein each of the two mounting plates defines a limiting slot; a limiting piece extends from each of the two side plates; the limiting piece is received in the limiting slot; and the limiting piece is slid in the limiting slot when the handle is slid between the locked position and the unlocked position.

15. The mounting apparatus of claim 14, wherein the limiting piece is substantially perpendicular to the operating plate and the two side plates.

16. The mounting apparatus of claim 14, wherein an extending direction of the limiting slot is substantially perpendicular to the operating plate.

17. The mounting apparatus of claim 13, wherein each of the two sliding slots comprises a guiding portion and a sliding portion substantially perpendicular to the guiding portion; each of the two positioning post is engaged in the sliding portion through the guiding portion; and an extending direction of the sliding portion is substantially parallel to the operating plate.

18. The mounting apparatus of claim 11, wherein each of the two mounting portions comprises two mounting pieces; when the handle is in the locked position, the two mounting pieces abut two side edges of each of the first cutout and the second cutout.

19. The mounting apparatus of claim 18, wherein an acute angle is defined between the two mounting pieces.

20. The mounting apparatus of claim 11, wherein each of the first cutout and the second cutout is substantially trapezoidal.
